(19) United States
(12) Patent Application Publication
(10) Pub. No.: US 2026/0223635 A1
(43) Pub. Date: Jul. 30, 2026

(54) WAFER PLACEMENT TABLE

(71) Applicant: NGK INSULATORS, LTD., Nagoya-shi (JP)

(72) Inventors: Seiya INOUE, Handa-shi (JP); Tatsuya KUNO, Nagoya-shi (JP); Natsuki HIRATA, Nagoya-shi (JP); Katsutomo TAKATSU, Handa-shi (JP)

(21) Appl. No.: 19/629,539

(22) Filed: Mar. 26, 2026

Related U.S. Application Data
(63) Continuation of application No. PCT/JP2025/022795, filed on Jun. 25, 2025.

(30) Foreign Application Priority Data
Sep. 12, 2024 (JP) 2024-158444

(51) Int. Cl. H10P 72/72; H01J 37/32

(52) U.S. Cl. CPC H10P 72/722; H01J 37/32724

(57) ABSTRACT

A wafer placement table includes: a ceramic plate incorporating an electrode; a base plate having a refrigerant flow path therein; a stepped hole penetrating the base plate in an up-down direction and having an upper hole portion, a lower hole portion, and a hole step portion; an insulating tube inserted into the upper hole portion; a resin tube inserted into the lower hole portion, having an upper surface bonded to the hole step portion, and having a larger diameter than the insulating tube; and a power feeding member having an upper surface connected to the electrode and inserted into the insulating tube and the resin tube. On the upper surface of the resin tube, a convex member for securing a gap between the upper surface of the resin tube and the hole step portion of the stepped hole is provided, and the adhesive layer is filled in the gap.

### CROSS-REFERENCE TO RELATED APPLICATION

This application is a continuation application of PCT/JP2025/022795, filed on Jun. 25, 2025, which claims the benefit of priority Japanese Patent Application No. 2024-158444 filed on Sep. 12, 2024, the entire contents of which are incorporated herein by reference.

### BACKGROUND OF THE INVENTION

### 1. Field of the Invention

The present invention relates to a wafer placement table.

### 2. Description of the Related Art

Conventionally, a wafer placement table including an insulating ceramic plate incorporating an electrode, and a conductive cooling plate having a refrigerant flow path therein, has been known. For example, the wafer placement table described in PTL 1 includes a stepped hole penetrating the cooling plate in an up-down direction. The stepped hole has an upper hole portion having a small diameter, a lower hole portion having a large diameter, and a hole step portion between the upper hole portion and the lower hole portion. A ceramic insulating tube is inserted into the upper hole portion of the stepped hole. A resin tube (fixing plate) having a larger diameter than the insulating tube is disposed in the lower hole portion of the stepped hole. A lower surface of the insulating tube is inserted into an upper surface of the resin tube. A power feeding member is inserted into the insulating tube and the resin tube. An upper surface of the power feeding member is connected to the electrode. In PTL 1, fixing between the resin tube and the cooling plate by screwing is exemplified.

### CITATION LIST

### Patent Literature

PTL 1: JP2015-207765A

### SUMMARY OF THE INVENTION

Meanwhile, in PTL 1, it is also conceivable to fix an upper surface of the resin tube and the hole step portion of the cooling plate by an adhesive layer (such a configuration is not described in PTL 1). However, in that case, when a thickness of the adhesive layer is thin (for example, 20 to 30 μm), shear strain due to a thermal expansion difference between the resin tube and the cooling plate during use of the wafer placement table is large, and the fixing plate has sometimes peeled off.

The present invention has been made to solve such a problem, and its primary object is to prevent a resin tube fixed to a base plate via an adhesive layer from peeling off.

[1] A wafer placement table of the present invention includes: a ceramic plate having a wafer placement surface on an upper surface and incorporating an electrode; a base plate provided on a lower surface side of the ceramic plate and having a refrigerant flow path therein; a stepped hole penetrating the base plate in an up-down direction and having an upper hole portion having a small diameter, a lower hole portion having a large diameter, and a hole step portion between the upper hole portion and the lower hole portion, the lower hole portion being provided below the refrigerant flow path; an insulating tube inserted into the upper hole portion; a resin tube inserted into the lower hole portion, having an upper surface bonded to the hole step portion via an adhesive layer, and having a larger diameter than the insulating tube; and a power feeding member having an upper surface connected to the electrode and inserted into the insulating tube and the resin tube, wherein, on the upper surface of the resin tube, a convex member for securing a gap between the upper surface of the resin tube and the hole step portion of the stepped hole is provided, and the adhesive layer is filled in the gap.

In this wafer placement table, the power feeding member is inserted into the insulating tube and the resin tube provided in the stepped hole of the base plate. The insulating tube is inserted into the upper hole portion of the stepped hole. The resin tube having a larger diameter than the insulating tube is inserted into the lower hole portion of the stepped hole, and its upper surface is bonded to the hole step portion of the stepped hole via the adhesive layer. On the upper surface of the resin tube, the convex member for securing the gap between the upper surface of the resin tube and the hole step portion of the stepped hole is provided, and the adhesive layer is filled in the gap. Therefore, in this wafer placement table, as compared with a case where the upper surface of the resin tube is flat, the adhesive layer can be made thicker, and shear strain of the adhesive layer can be reduced. As a result, in an environment in which high and low temperatures are repeated, the adhesive layer becomes less likely to break and the resin tube becomes less likely to peel off.

In this specification, up and down, left and right, and front and back, for example, are used to describe the present invention, but up and down, left and right, and front and back represent only a relative positional relationship. Thus, when the orientation of the wafer placement table is changed, up and down may become left and right, or left and right may become up and down. Such cases are also included in the technical scope of the present invention.

[2] In the wafer placement table of the present invention (the wafer placement table according to [1] above), the convex member may be a ring member. In this manner, the convex member can be formed relatively easily.

[3] In the wafer placement table of the present invention (the wafer placement table according to [1] above), the convex member may be composed of a plurality of small projections having the same height. In this manner, an adhesion area between the hole step portion of the stepped hole of the base plate and the upper surface of the resin tube is easily increased.

[4] In the wafer placement table of the present invention (the wafer placement table according to any one of [1] to [3] above), the convex member may be provided so as to be in contact with an outer edge of the upper surface of the resin tube. In this manner, as compared with a case where the convex member is provided along an opening edge of a hole of the resin tube, the upper surface of the resin tube and the hole step portion are easily held in parallel.

[5] In the wafer placement table of the present invention (the wafer placement table according to any one of [1] to [4] above), a height of the convex member may be 50 μm or more and 300 μm or less. In this manner, as compared with a case where the upper surface of the resin tube is flat, the adhesive layer can be made sufficiently thick.

[6] In the wafer placement table of the present invention (the wafer placement table according to any one of [1] to [5] above), the resin tube may be formed of engineering plastic. Since engineering plastics have high heat resistance and many of them are less expensive than ceramics, they are suitable as a material of the resin tube.

[7] In the wafer placement table of the present invention (the wafer placement table according to any one of [1] to [6] above), a lower end of the insulating tube may enter a stepped groove provided on the upper surface of the resin tube. In this manner, insulation between the power feeding member and the base plate becomes higher.

[8] In the wafer placement table of the present invention (the wafer placement table according to any one of [1] to [7] above), the base plate may have an average linear expansion coefficient of 10 ppm/K or less at 40 to 570°C. In this manner, a difference in linear expansion between the base plate and the resin tube becomes large, and thus the effect obtained when applying the present invention is large.

[9] In the wafer placement table of the present invention (the wafer placement table according to any one of [1] to [8] above), a material of the base plate may be a composite material of metal and ceramic. Since composite materials of metal and ceramic are generally difficult-to-machine materials, it is meaningful to fix the resin tube by adhesion instead of screw fixing.

### BRIEF DESCRIPTION OF THE DRAWINGS

FIG. 1 is a plan view of a wafer placement table 10.

FIG. 2 is a cross-sectional view taken along line A-A in FIG. 1.

FIG. 3 is a partially enlarged view of FIG. 2.

FIG. 4A is a plan view of a resin tube 60.

FIG. 4B is a cross-sectional view taken along line B-B in FIG. 4A.

FIG. 5 is a graph representing a relationship between shear strain and shear strength of an adhesive layer 80 after heat treatment.

FIG. 6 is a partial cross-sectional view of an embodiment using a resin tube 160.

FIG. 7A is a plan view of the resin tube 160.

FIG. 7B is a cross-sectional view taken along line C-C in FIG. 7A.

FIG. 8 is a partial cross-sectional view of an embodiment using a resin tube 260.

FIG. 9A is a plan view of the resin tube 260.

FIG. 9B is a cross-sectional view taken along line D-D in FIG. 9A.

FIG. 10 is a partial cross-sectional view of another embodiment.

FIG. 11 is a partial cross-sectional view of another embodiment.

### DETAILED DESCRIPTION OF THE INVENTION

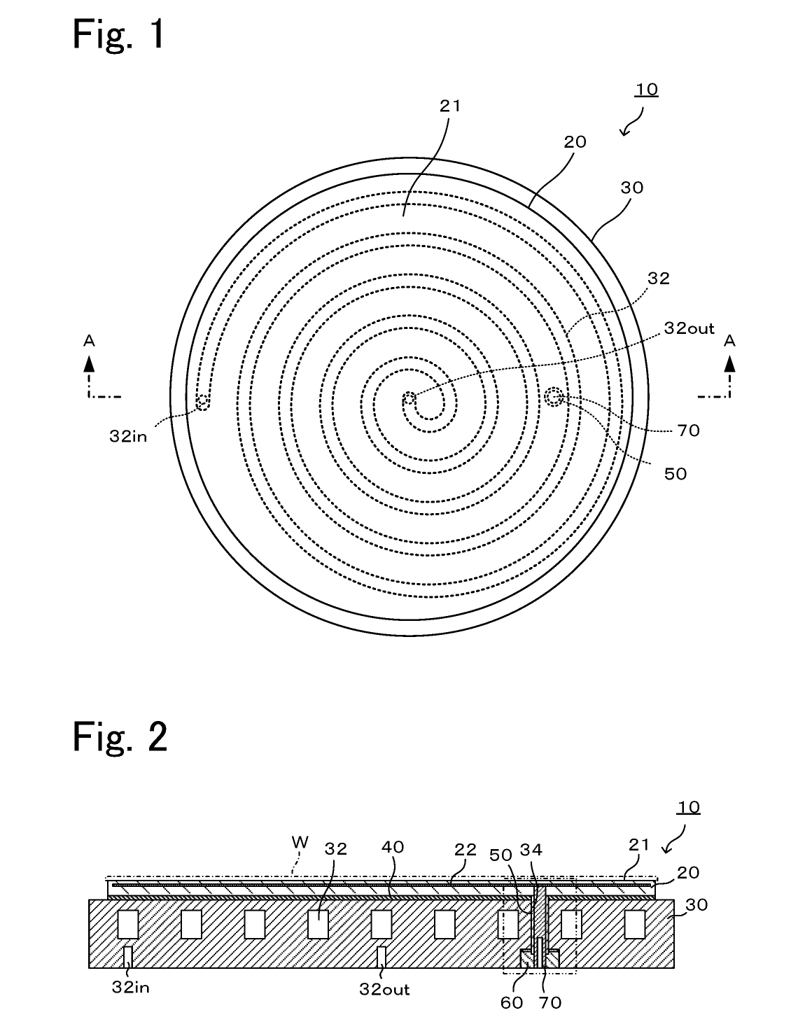

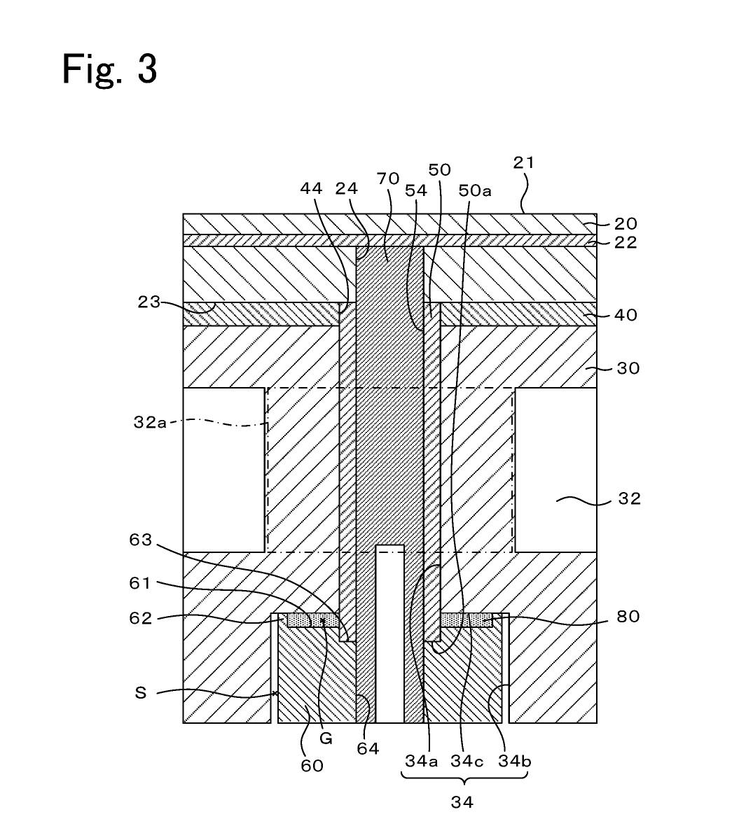

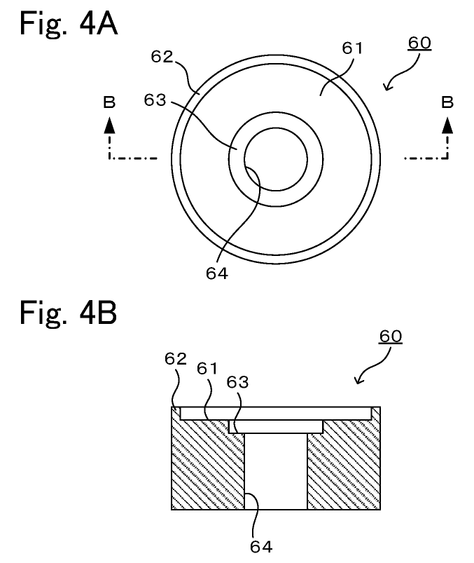

Preferred embodiments of the present invention will be described with reference to the drawings. FIG. 1 is a plan view of a wafer placement table 10, FIG. 2 is a cross-sectional view taken along line A-A in FIG. 1, FIG. 3 is a partially enlarged view of FIG. 2 (an enlarged view of a region within a frame indicated by a two-dot chain line), and FIGS. 4A and 4B are explanatory views of a resin tube 60.

As shown in FIG. 2, the wafer placement table 10 includes a ceramic plate 20, a base plate 30, a bonding layer 40, a base plate through-hole 34, an insulating tube 50, a resin tube 60, and a power feeding member 70.

The ceramic plate 20 is a ceramic disk such as an alumina sintered body or an aluminum nitride sintered body (for example, a disk having a diameter of 300 mm and a thickness of 5 mm). An upper surface of the ceramic plate 20 serves as a wafer placement surface 21 on which a wafer W is placed. The ceramic plate 20 incorporates an electrostatic electrode 22. Although not illustrated, an annular seal band is formed along an outer edge of the wafer placement surface 21 of the ceramic plate 20, and a plurality of circular small projections are formed over an entire region inside the seal band. The electrostatic electrode 22 is a planar mesh electrode and is connected, via the power feeding member 70, to an external DC power supply not shown. When a DC voltage is applied to the electrostatic electrode 22, the wafer W is attracted and fixed to the wafer placement surface 21 by electrostatic attraction, and when application of the DC voltage is released, attraction and fixation of the wafer W to the wafer placement surface 21 is released.

The base plate 30 is a disk having good electrical conductivity and thermal conductivity (for example, a disk having the same diameter as or a diameter larger than that of the ceramic plate 20, and having a thickness of 25 mm). Inside the base plate 30, a refrigerant flow path 32 through which a refrigerant circulates is formed. The refrigerant flowing through the refrigerant flow path 32 is preferably a liquid and is preferably electrically insulating. Examples of electrically insulating liquids include fluorine-based inert liquids. As shown in FIG. 1, the refrigerant flow path 32 is formed in a spiral shape in a one-stroke pattern from one end (an inlet 32in) to the other end (an outlet 32out) over the entirety of the base plate 30 in plan view. A supply port and a recovery port of an external refrigerant device (not shown) are respectively connected to the inlet 32in and the outlet 32out of the refrigerant flow path 32. A refrigerant supplied from the supply port of the external refrigerant device to the inlet 32in of the refrigerant flow path 32 passes through the refrigerant flow path 32 and returns from the outlet 32out of the refrigerant flow path 32 to the recovery port of the external refrigerant device, is temperature-controlled, and is supplied again from the supply port to the inlet 32in of the refrigerant flow path 32. The base plate 30 is connected to a radio-frequency (RF) power supply and is also used as an RF electrode.

Examples of materials for the base plate 30 include metallic materials or composite materials of metal and ceramic. Examples of metallic materials include Al, Ti, Mo, or alloys thereof. Examples of composite materials of metal and ceramic include metal matrix composites (MMC) and ceramic matrix composites (CMC). Specific examples of such composite materials include materials containing Si, SiC, and Ti (also referred to as SiSiCTi), materials obtained by impregnating Al and/or Si into a SiC porous body (also referred to as AlSiC), and composite materials of Al₂O₃ and TiC. As the material of the base plate 30, it is preferable to select one having a thermal expansion coefficient close to that of the material of the ceramic plate 20. For example, when the material of the ceramic plate 20 is alumina, as the material of the base plate 30, a material having a thermal expansion coefficient of 4.4 to 14.2 ppm/K (for example, antimony, gold, tungsten, titanium, pure iron, cast iron, carbon steel, chromium steel, chromium-nickel steel, nickel-chromium alloy, nickel, Monel metal, platinum, platinum-iridium, molybdenum, thorium, zirconium, carbon, beryllium, niobium, chromium, cobalt, iridium, palladium, etc.) may be used. Among these, from a viewpoint of a difference in thermal expansion coefficient between the ceramic plate 20 and the base plate 30 and productivity of the base plate 30, titanium, SiSiCTi, or AlSiC is preferable as the material of the base plate 30.

The bonding layer 40 is, here, a metal layer and joins a lower surface of the ceramic plate 20 and an upper surface of the base plate 30. The metal layer can be formed using a metal bonding material (for example, Al–Mg bonding material or Al–Si–Mg bonding material) by well-known thermal compression bonding (TCB).

The base plate through-hole 34 is a circular hole in cross-section penetrating the base plate 30 in an up-down direction, and is provided so as not to penetrate the refrigerant flow path 32. The base plate through-hole 34 is a stepped hole, and as shown in FIG. 3, includes an upper hole portion 34a having a small diameter, a lower hole portion 34b having a large diameter, and a hole step portion 34c between the upper hole portion 34a and the lower hole portion 34b. The upper hole portion 34a penetrates, in an up-down direction, a formation region 32a of the refrigerant flow path 32 of the base plate 30 (a wall portion separating the refrigerant flow paths 32 of the base plate 30). The upper hole portion 34a communicates with a bonding layer through-hole 44 penetrating the bonding layer 40 in the up-down direction. The lower hole portion 34b is formed below the refrigerant flow path 32 and has a larger diameter than the upper hole portion 34a. Therefore, a diameter of the lower hole portion 34b can be made sufficiently large regardless of the shape of the refrigerant flow path 32. The lower hole portion 34b is formed so as to reach a lower surface of the base plate 30 from an outer peripheral position of the hole step portion 34c. A length of the upper hole portion 34a is longer than that of the lower hole portion 34b.

The insulating tube 50 is housed in the upper hole portion 34a of the base plate through-hole 34 and the bonding layer through-hole 44. The insulating tube 50 is electrically insulating and is a straight-shaped member made of ceramic such as alumina. The insulating tube 50 has an insulating tube through-hole 54 extending along a central axis of the insulating tube 50. The insulating tube 50 is fixed to an inner peripheral surface of the upper hole portion 34a of the base plate through-hole 34 via an adhesive layer not shown. A lower end 50a of the insulating tube 50 enters a stepped groove 63 provided on an upper surface 61 of the resin tube 60.

The resin tube 60 is housed in the lower hole portion 34b of the base plate through-hole 34. The resin tube 60 is a straight-shaped member made of an electrically insulating resin. As a material of the resin tube 60, a heat-resistant resin can be used. Examples of such resins include engineering plastics (including super engineering plastics), specifically PEEK (polyether ether ketone), PPA (aromatic polyamide), PPS (polyphenylene sulfide), PSU (polysulfone), PES (polyether sulfone), PEI (polyether imide), PAI (polyamide imide), etc. Among these, PEEK is preferable from viewpoints of heat resistance and a difference in thermal expansion coefficient with the base plate 30. A thermal expansion coefficient of the resin is not particularly limited, but is preferably 30 ppm/K or more and 200 ppm/K or less. Also, a difference in thermal expansion coefficient with the base plate 30 is not particularly limited, but is preferably 25 ppm/K or more and 185 ppm/K or less.

The resin tube 60 has a resin tube through-hole 64 extending along a central axis of the resin tube 60. The resin tube through-hole 64 communicates with the insulating tube through-hole 54. An outer diameter of the resin tube 60 is larger than an outer diameter of the insulating tube 50. That is, the resin tube 60 has a larger diameter than the insulating tube 50. By doing so, a creepage distance (insulation distance) between an outer peripheral surface of the power feeding member 70 and an inner peripheral surface of the lower hole portion 34b of the base plate through-hole 34 is increased. The outer diameter of the resin tube 60 is preferably 15 mm or more and 50 mm or less, for example. On the upper surface 61 of the resin tube 60, a protruding ring 62 concentric with the resin tube 60 is provided. The protruding ring 62 is a member that secures a gap G between the upper surface 61 of the resin tube 60 and the hole step portion 34c of the base plate through-hole 34. The gap G is secured by an upper surface of the protruding ring 62 coming into contact with the hole step portion 34c. The gap G is filled with an adhesive layer 80. The adhesive layer 80 is preferably formed of an elastic adhesive (for example, silicone or modified silicone). The protruding ring 62 is provided so as to be in contact with an outer edge of the upper surface 61 of the resin tube 60. That is, an outer diameter of the protruding ring 62 coincides with an outer diameter of the upper surface 61 of the resin tube 60. A height of the protruding ring 62 is preferably 50 μm or more and 300 μm or less.

A space S is provided between an outer peripheral surface of the resin tube 60 and an inner peripheral surface of the lower hole portion 34b of the base plate through-hole 34. When the wafer placement table 10 is used in an environment in which high and low temperatures are repeated, a thermal expansion difference occurs between the resin tube 60 and the base plate 30, and the space S is provided so as to be wider than this thermal expansion difference. The adhesive layer 80 may enter a part of the space S. Also, the adhesive layer 80 may enter between the upper surface of the protruding ring 62 and the hole step portion 34c.

The power feeding member 70 is, for example, a metal rod. Metals used for the power feeding member 70 include, for example, W, Mo, and Ni, and it is preferable that a thermal expansion coefficient of the metal is close to a thermal expansion coefficient of the ceramic plate 20. The power feeding member 70 is inserted into the resin tube through-hole 64, the insulating tube through-hole 54, and a ceramic plate bottomed hole 24, and is electrically connected to the electrostatic electrode 22 exposed at a bottom of the ceramic plate bottomed hole 24. The ceramic plate bottomed hole 24 is a substantially cylindrical hole provided from the lower surface 23 of the ceramic plate 20 to the electrostatic electrode 22. The power feeding member 70 is electrically insulated from the base plate 30 by the insulating tube 50, the resin tube 60, and the adhesive layer 80. The outer peripheral surface of the power feeding member 70 may be in contact with or may not be in contact with an inner peripheral surface of the insulating tube 50 or an inner peripheral surface of the resin tube 60.

Next, an example of use of the wafer placement table 10 configured as described above will be explained. First, in a state where the wafer placement table 10 is installed in a chamber (not shown), a wafer W is placed on the wafer placement surface 21. Then, the chamber is depressurized by a vacuum pump to adjust a predetermined vacuum degree, and a DC voltage is applied to the electrostatic electrode 22 of the ceramic plate 20 to generate an electrostatic attraction force, thereby attracting and fixing the wafer W to the wafer placement surface 21. Next, a reaction gas atmosphere having a predetermined pressure (for example, several tens to several hundreds of Pa) is set in the chamber. In this state, an RF voltage is applied between an upper electrode (not shown) provided in a ceiling portion of the chamber and the base plate 30 of the wafer placement table 10 to generate plasma. A surface of the wafer W is processed by the generated plasma. A refrigerant is circulated as appropriate through the refrigerant flow path 32 of the base plate 30. When processing the wafer W with plasma in this manner, heat input by the plasma is removed by the base plate 30, and the wafer placement surface 21 is controlled to a desired temperature. At this time, the power feeding member 70 is electrically insulated from the base plate 30 by the insulating tube 50, the resin tube 60, and the adhesive layer 80. Thus, discharge between the power feeding member 70 and the base plate 30 can be suppressed.

In the wafer placement table 10 described in detail above, the power feeding member 70 is inserted into the insulating tube 50 and the resin tube 60 provided in the base plate through-hole 34 (the stepped hole of the base plate 30). The insulating tube 50 is inserted into the upper hole portion 34a. The resin tube 60 having a larger diameter than the insulating tube 50 is inserted into the lower hole portion 34b, and its upper surface 61 is bonded to the hole step portion 34c via the adhesive layer 80. On the upper surface 61 of the resin tube 60, the protruding ring 62 (convex member) for securing the gap G between the upper surface 61 of the resin tube 60 and the hole step portion 34c of the base plate through-hole 34 is provided, and the adhesive layer 80 is filled in the gap G. Therefore, in this wafer placement table 10, as compared with a case where the upper surface 61 of the resin tube 60 is flat, the adhesive layer 80 can be made thicker, and shear strain of the adhesive layer 80 can be reduced. As a result, in an environment in which high and low temperatures are repeated, the adhesive layer 80 becomes less likely to break and the resin tube 60 becomes less likely to peel off.

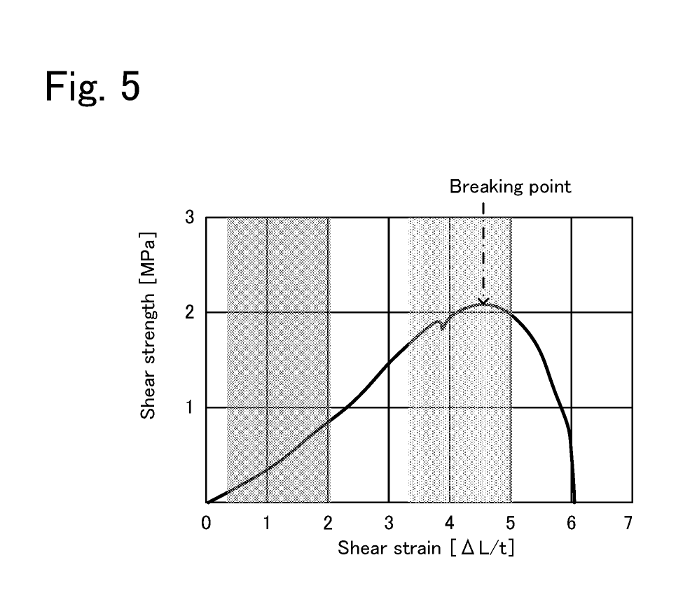

Shear strain of the adhesive layer 80 is represented by (thermal expansion difference ΔL between the base plate 30 and the resin tube 60)/(thickness t of the adhesive layer 80). For example, FIG. 5 shows an example of a graph representing a relationship between shear strain and shear strength of the adhesive layer 80 after heat treatment. Here, it is assumed that the thermal expansion difference ΔL is 100 μm. When the upper surface 61 of the resin tube 60 is a flat surface (a surface without the protruding ring 62), the thickness t of the adhesive layer 80 becomes approximately 20 to 30 μm. In that case, shear strain ΔL/t becomes 3.3 to 5 (see the light shaded portion in FIG. 5), but shear strain ΔL/t at a breaking point is about 4.5, and therefore there is a possibility that the adhesive layer 80 breaks. In contrast, when the protruding ring 62 is provided on the upper surface 61 of the resin tube 60 and the thickness t of the adhesive layer 80 is controlled to 50 to 300 μm, shear strain ΔL/t becomes 0.3 to 2 (see the dark shaded portion in FIG. 5), and since it is far from the breaking point, the possibility that the adhesive layer 80 breaks is small.

Further, the protruding ring 62 can be formed relatively easily on the upper surface 61 of the resin tube 60 by grinding or the like during a process of manufacturing the resin tube 60.

Further, the protruding ring 62 is provided so as to be in contact with the outer edge of the upper surface 61 of the resin tube 60. Therefore, as compared with a case where the protruding ring 62 is provided along an opening edge of the resin tube through-hole 64, an attitude when the protruding ring 62 is brought into contact with the hole step portion 34c is easily stabilized. Therefore, the upper surface 61 of the resin tube 60 and the hole step portion 34c are easily held in parallel.

Further, a height of the protruding ring 62 is preferably 50 μm or more and 300 μm or less. In this manner, as compared with a case where the upper surface 61 of the resin tube 60 is flat, the adhesive layer 80 can be made sufficiently thick.

Then, the resin tube 60 may be formed of engineering plastic. Since engineering plastics have high heat resistance and many of them are less expensive than ceramics, they are suitable as a material of the resin tube 60.

Then also, the lower end 50a of the insulating tube 50 enters the stepped groove 63 provided on the upper surface 61 of the resin tube 60. Therefore, insulation between the power feeding member 70 and the base plate 30 becomes higher.

Then further, it is preferable that the base plate 30 has an average linear expansion coefficient of 10 ppm/K or less at 40 to 570°C. In this manner, a difference in linear expansion between the base plate 30 and the resin tube 60 becomes large, and thus the effect obtained when applying the present invention is large. Examples of materials of the base plate 30 satisfying this condition include titanium, SiSiCTi, and AlSiC.

The material of the base plate 30 may be a composite material of metal and ceramic (described above). Since composite materials of metal and ceramic are generally difficult-to-machine materials, it is meaningful to fix the resin tube by adhesion instead of screw fixing.

It should be noted that the present invention is not limited to the embodiments described above in any way, and it is needless to say that the present invention can be carried out in various modes as long as they fall within the technical scope of the present invention.

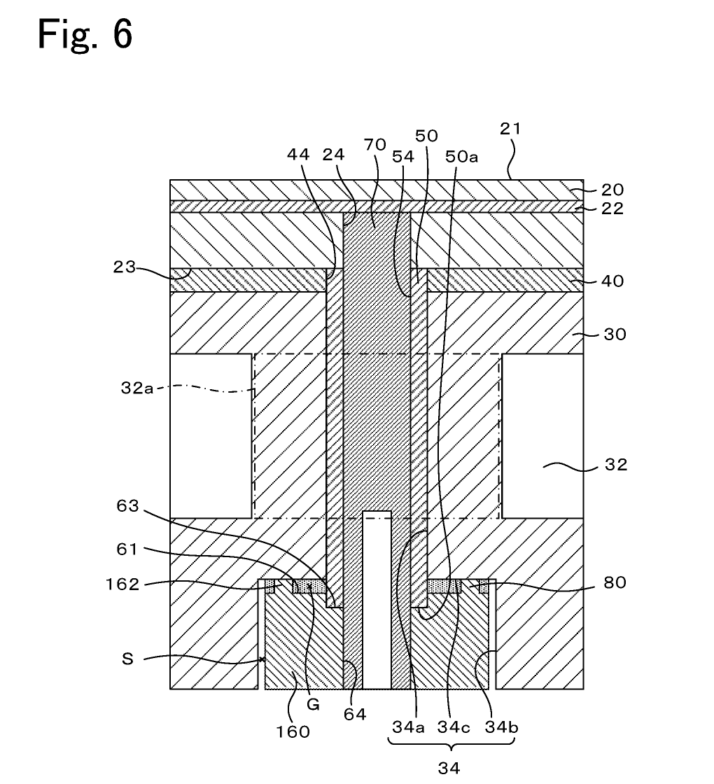

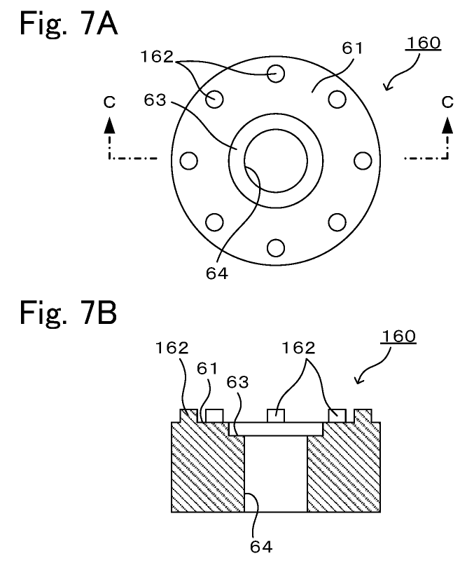

In the embodiments described above, the protruding ring 62 is provided on the upper surface 61 of the resin tube 60 along the outermost periphery, but it is not particularly limited thereto. For example, as shown in FIGS. 6, 7A, and 7B, a resin tube 160 may be employed instead of the resin tube 60 of the embodiments described above. In FIGS. 6, 7A, and 7B, the same reference numerals are assigned to the same constituent elements as in the above-described embodiments. On the upper surface 61 of the resin tube 160, a plurality of small projections 162 having the same height are provided at equal intervals on a circumference concentric with the resin tube 160. Also in this manner, as compared with a case where the upper surface 61 of the resin tube 160 is flat, the adhesive layer 80 can be made thicker, and therefore the adhesive layer 80 becomes less likely to break and the resin tube 160 becomes less likely to peel off. In this case, an adhesion area between the hole step portion 34c of the base plate through-hole 34 and the upper surface 61 of the resin tube 160 is easily increased. A circumference on which the plurality of small projections 162 are disposed is preferably located on an outer edge side rather than on a resin tube through-hole 64 side. The plurality of small projections 162 may be provided at random intervals on a circumference concentric with the resin tube 160. The plurality of small projections 162 may be disposed regularly (for example, in a lattice) or randomly over the entirety of the upper surface 61 of the resin tube 160.

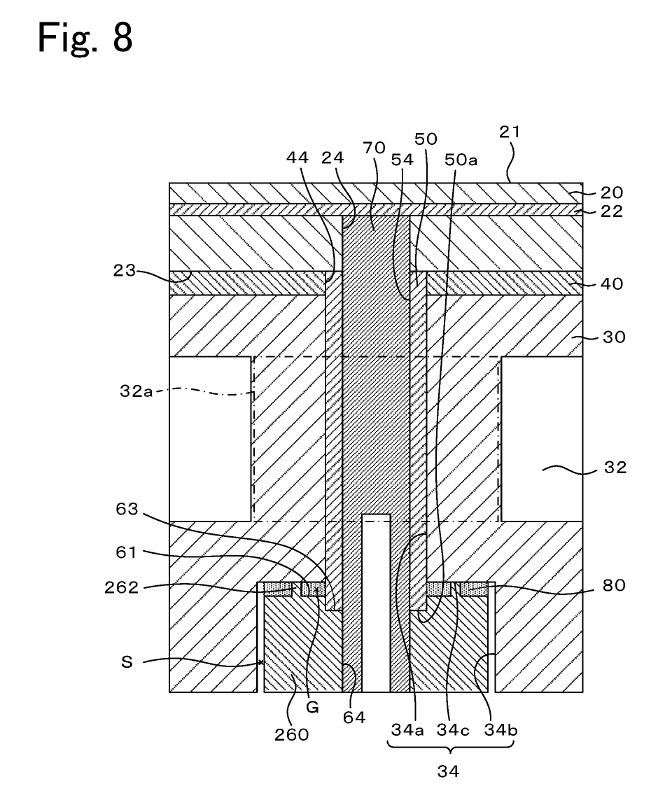

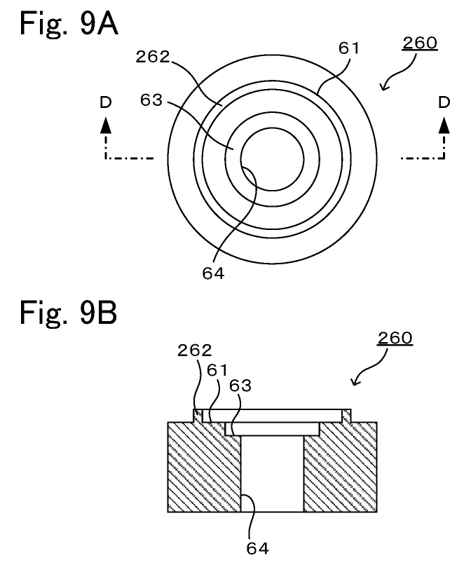

Alternatively, as shown in FIGS. 8, 9A, and 9B, a resin tube 260 may be employed instead of the resin tube 60 of the embodiments described above. In FIGS. 8, 9A, and 9B, the same reference numerals are assigned to the same constituent elements as in the above-described embodiments. On the upper surface 61 of the resin tube 260, a protruding ring 262 concentric with the resin tube 260 is provided. The protruding ring 262 is not in contact with the outer edge of the upper surface 61 of the resin tube 260, and is provided between the outer edge of the upper surface 61 and a center of the upper surface 61. An outer diameter of the protruding ring 262 is smaller than an outer diameter of the upper surface 61 of the resin tube 260. Also in this manner, as compared with a case where the upper surface 61 of the resin tube 260 is flat, the adhesive layer 80 can be made thicker, and therefore the adhesive layer 80 becomes less likely to break and the resin tube 260 becomes less likely to peel off. However, since the protruding ring 262 is provided between the outer edge of the upper surface 61 and the center of the upper surface 61, an attitude when the protruding ring 262 is brought into contact with the hole step portion 34c is less stable as compared with the above-described embodiments.

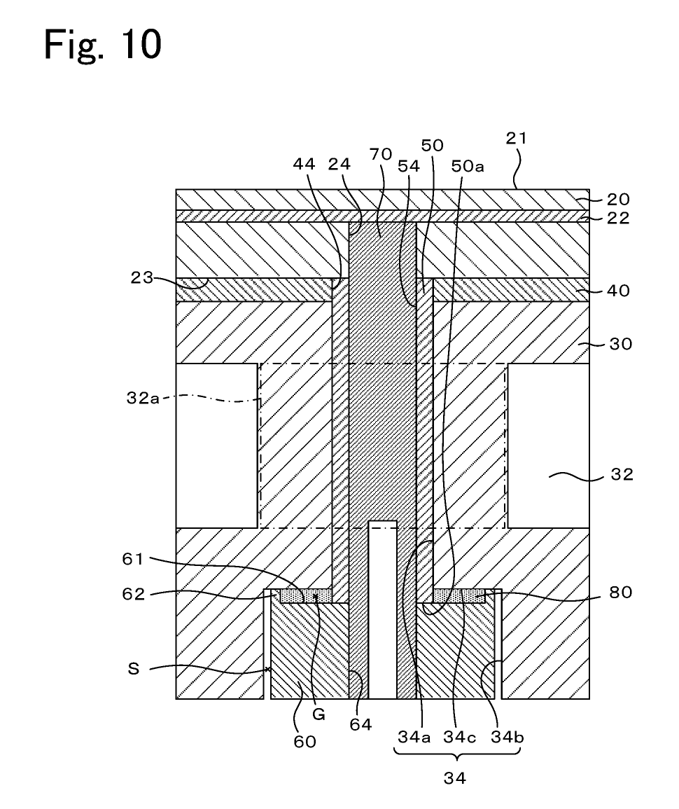

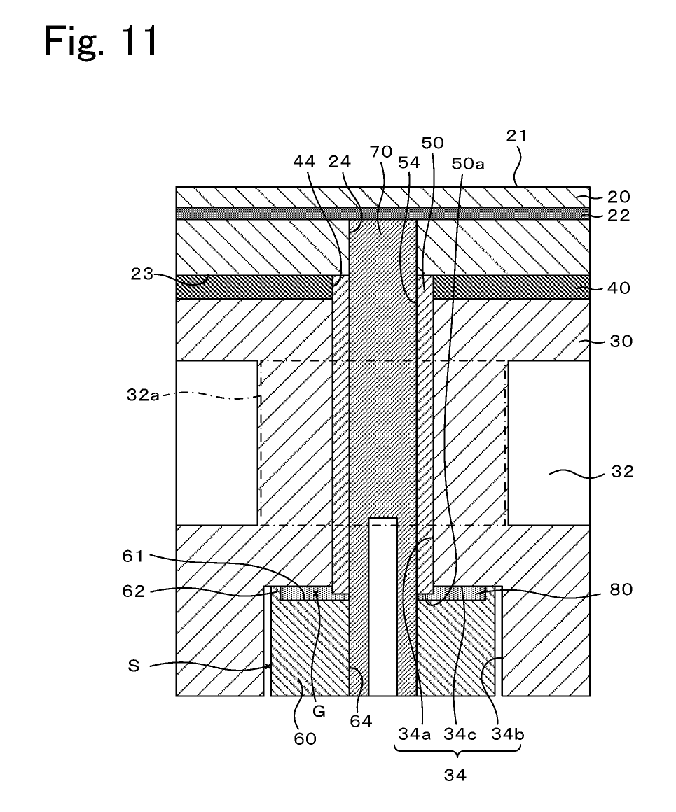

In the embodiments described above, the lower end 50a of the insulating tube 50 is made to enter the stepped groove 63 provided on the upper surface 61 of the resin tube 60, but it is not particularly limited thereto. For example, as shown in FIG. 10, the stepped groove 63 may not be provided on the upper surface 61 of the resin tube 60, and the lower end 50a of the insulating tube 50 may be brought into contact with the upper surface 61 of the resin tube 60. Alternatively, as shown in FIG. 11, the lower end 50a of the insulating tube 50 may be positioned between the upper surface 61 of the resin tube 60 and the hole step portion 34c of the base plate through-hole 34. In this case, the lower end 50a of the insulating tube 50 is positioned inside the adhesive layer 80. However, considering insulation between the power feeding member 70 and the base plate 30, it is preferable, as in the above-described embodiments, that the lower end 50a of the insulating tube 50 is made to enter the stepped groove 63 provided on the upper surface 61 of the resin tube 60. In FIGS. 10 and 11, the same reference numerals are assigned to the same constituent elements as in the above-described embodiments.

In the embodiments described above, the insulating tube 50 is made of ceramic, but it may be made of resin. However, since resin generally has poorer thermal conductivity as compared with ceramic, a resin-made insulating tube 50 has lower heat removal performance as compared with a ceramic-made insulating tube 50. Therefore, it is preferable that the insulating tube 50 is made of ceramic.

In the embodiments described above, the bonding layer 40 is exemplified as a metal layer, but it is not particularly limited thereto. For example, a resin layer may be adopted as the bonding layer 40, or an inorganic adhesive may be adopted. Examples of materials for the resin layer include insulating resins such as epoxy resin, acrylic resin, and silicone resin. The bonding layer 40 may also be one in which a filler is contained in the insulating resin. The filler is preferably a material having higher thermal conductivity than the insulating resin of the bonding layer 40, and for example, alumina or aluminum nitride may be used. The bonding layer 40 is preferably a metal layer from a viewpoint of thermal conductivity.

In the embodiments described above, the electrostatic electrode 22 is incorporated in the ceramic plate 20, but it is not particularly limited thereto. For example, in place of or in addition to the electrostatic electrode 22, a heater electrode (resistive heating element) may be incorporated, or an electrode for generating plasma (RF electrode) may be incorporated.

What is claimed is:

1. A wafer placement table comprising:
a ceramic plate having a wafer placement surface on its upper surface and incorporating an electrode;
a base plate provided on a lower surface side of the ceramic plate and having a refrigerant flow path therein;
a stepped hole penetrating the base plate in an up-down direction and having an upper hole portion having a small diameter, a lower hole portion having a large diameter, and a hole step portion between the upper hole portion and the lower hole portion, the lower hole portion being provided below the refrigerant flow path;
an insulating tube inserted into the upper hole portion;
a resin tube inserted into the lower hole portion, having an upper surface bonded to the hole step portion via an adhesive layer, and having a larger diameter than the insulating tube; and
a power feeding member having an upper surface connected to the electrode and inserted into the insulating tube and the resin tube,
wherein, on the upper surface of the resin tube, a convex member for securing a gap between the upper surface of the resin tube and the hole step portion of the stepped hole is provided, and the adhesive layer is filled in the gap.

2. The wafer placement table according to claim 1,
wherein the convex member is a ring member.

3. The wafer placement table according to claim 1,
wherein the convex member is composed of a plurality of small projections having the same height.

4. The wafer placement table according to claim 1,
wherein the convex member is provided so as to be in contact with an outer edge of the upper surface of the resin tube.

5. The wafer placement table according to claim 1,
wherein a height of the convex member is 50 μm or more and 300 μm or less.

6. The wafer placement table according to claim 1,
wherein the resin tube is formed of engineering plastic.

7. The wafer placement table according to claim 1,
wherein a lower end of the insulating tube enters a stepped groove provided on the upper surface of the resin tube.

8. The wafer placement table according to claim 1,
wherein the base plate has an average linear expansion coefficient of 10 ppm/K or less at 40 to 570° C.

9. The wafer placement table according to claim 1,
wherein a material of the base plate is a composite material of metal and ceramic.
